(19) United States
(12) Patent Application Publication
(10) Pub. No.: US 2008/0218964 A1
(43) Pub. Date: Sep. 11, 2008

(54) DESKTOP PERSONAL COMPUTER AND THERMAL MODULE THEREOF

(75) Inventor: Chia-Yi Chang, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: DFI, INC., Taipei Hsien (TW)

(21) Appl. No.: 11/864,986

(22) Filed: Sep. 29, 2007

(30) Foreign Application Priority Data
Mar. 5, 2007 (TW) 96107472
Jun. 1, 2007 (TW) 96119759

(51) Int. Cl. H05K 7/20

(52) U.S. Cl. 361/687; 361/702

(57) ABSTRACT

A thermal module adapted for a desktop personal computer is provided. The desktop personal computer comprises a motherboard including a central processing unit and electronic elements. The thermal module comprises a first heat sink, at least one second heat sink, and a heat conductive plate. The first heat sink is disposed above the central processing unit. The second heat sink is disposed above one of the electronic elements. The heat conductive plate is coupled to the second heat sink, extends from the second heat sink to the central processing unit, and is engagingly sandwiched between the central processing unit and the first heat sink.

### CROSS-REFERENCE TO RELATED APPLICATION

This application claims the priority benefits of Taiwan applications serial no. 96119759, filed Jun. 1, 2007 and serial no. 96107472, filed Mar. 5, 2007. All disclosures of the Taiwan applications are incorporated herein by reference.

### BACKGROUND OF THE INVENTION

1. Field of the Invention

The present invention relates to a desktop personal computer and a thermal module thereof, and more particularly, to a desktop personal computer operable with low noise and a thermal module thereof.

2. Description of Related Art

Current desktop personal computers generally include a motherboard with a plurality of electronic elements mounted thereon. These electronic elements include, for example, a central processing unit (CPU), a pulse width modulator (PWM), and a north bridge chip, which generate a considerable amount of heat during operation, resulting in a rise of the temperature of these electronic elements.

If the heat is not timely removed and thus get accumulated in the electronic elements, the temperature of the electronic elements will continuously rise and exceed over their normal operating temperatures leading to overheating. The overheating may result in a temporary or permanent failure of these electronic elements, and thereby causing operation of the desktop personal computer unstable or even crash of the desktop personal computer. If the temperature of the electronic elements is too high, a permanent failure of the electronic elements may occur.

To lower the temperature of the electronic elements during operation, a plurality of heat sinks are usually disposed on the electronic elements, especially on the CPU, PWM, and north bridge chip. In addition, since the CPU generates more heat, usually, a cooling system for the CPU is specially and independently designed. The electronic elements other than the CPU usually dissipate the heat thereof through fin type heat sinks optionally combined with fans.

### SUMMARY OF THE INVENTION

The present invention is directed to a thermal module for dissipating heat generated by a central processing unit and electronic elements of a desktop personal computer.

The present invention is also directed to a desktop personal computer which includes a thermal module for dissipating the heat generated by a central processing unit and electronic elements.

The present invention provides a thermal module suitable for a desktop personal computer. The desktop personal computer comprises a motherboard including a central processing unit and a plurality of electronic elements. The thermal module comprises a first heat sink, at least one second heat sink and a heat conductive plate. The first heat sink is disposed above the central processing unit. The second heat sink is disposed above one of the electronic elements. The heat conductive plate is coupled to the second heat sink, extends from the second heat sink to the central processing unit, and is engagingly sandwiched between the central processing unit and the first heat sink.

According to an embodiment of the present invention, the heat conductive plate is a metal plate.

According to an embodiment of the present invention, the first heat sink includes a cooling head of a liquid cooling device.

According to an embodiment of the present invention, the first heat sink is a fin type heat sink.

According to an embodiment of the present invention, the second heat sink is a fin type heat sink.

According to an embodiment of the present invention, the thermal module comprises at least one heat pipe and a plurality of the second heat sinks. The second heat sinks are disposed above the electronic elements, respectively. The heat conductive plate extends from one of the second heat sinks onto the central processing unit, and is engagingly sandwiched between the central processing unit and the first heat sink. The heat pipe interconnects the second heat sinks.

According to an embodiment of the present invention, the first heatsink and the second heat sinks are connected in series through the heat conductive plate and the heat pipe.

The present invention also provides a desktop personal computer including a motherboard and a thermal module. The motherboard includes a circuit carrier, a central processing unit mounted on the circuit carrier, and a plurality of electronic elements mounted on the circuit carrier. The thermal module includes a first heat sink, at least one second heat sink and a heat conductive plate. The first heat sink is disposed above the central processing unit. The second heat sink is disposed above one of the electronic elements. The heat conductive plate is coupled to the second heat sink, extends from the second heat sink to the central processing unit, and is engagingly sandwiched between the central processing unit and the first heat sink.

According to an embodiment of the present invention, the heat conductive plate is a metal plate.

According to an embodiment of the present invention, the electronic elements include a pulse width modulator, a south bridge chip, and a north bridge chip.

According to an embodiment of the present invention, the desktop personal computer further comprises at least one heat pipe and a plurality of the second heat sinks. The second heat sinks are disposed above the electronic elements, respectively. The heat conductive plate extends from one of the second heat sinks onto the central processing unit, and is engagingly sandwiched between the central processing unit and the first heat sink. The heat pipe interconnects the second heat sinks.

According to an embodiment of the present invention, the heat conductive plate is coupled between the first heat sink, and the second heat sink above the pulse width modulator.

According to an embodiment of the present invention, the first heat sink and the second heat sinks are connected in series through the heat conductive plate and the heat pipe.

According to an embodiment of the present invention, the desktop personal computer further comprises a housing, wherein the circuit carrier is located inside the housing, and the first heat sink includes a cooling head of a liquid cooling device.

According to an embodiment of the present invention, the first heat sink is a fin type heat sink.

According to an embodiment of the present invention, the second heat sink is a fin type heat sink.

As described above, in the thermal module according to an embodiment of the present invention, the heat conductive plate is coupled to the second heat sink disposed above the electronic element, and is engagingly sandwiched between the central processing unit and the first heat sink disposed above the central processing unit. Therefore, the heat conductive plate makes it possible that the heat dissipation of the central processing unit and the electronic element can be done cooperatively by the first heat sink and the second heat sink.

In order to make the aforementioned and other features and advantages of the present invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a desktop personal computer according to an embodiment of the present invention.

FIG. 2 illustrates the electronic element and the central processing unit of FIG. 1.

### DESCRIPTION OF THE EMBODIMENTS

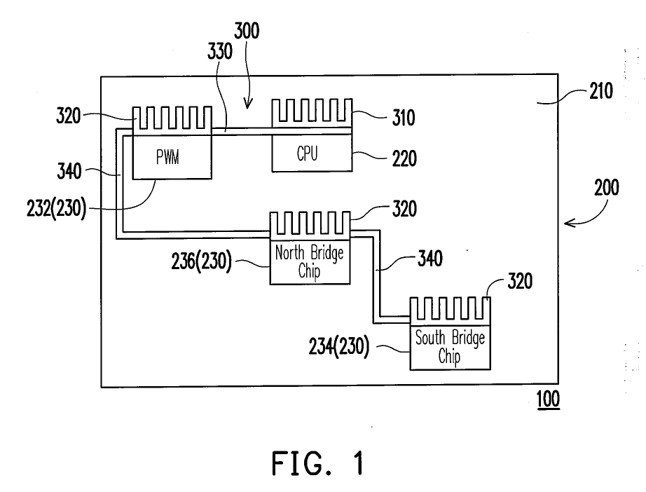

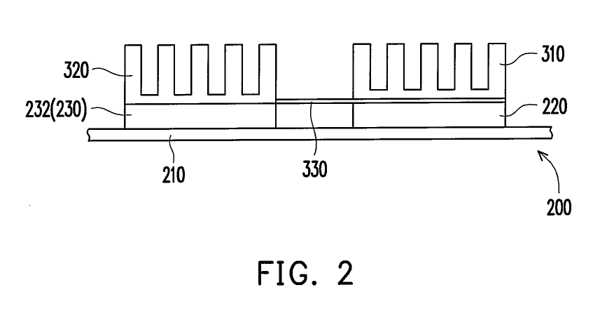

FIG. 1 illustrates a desktop personal computer according to an embodiment of the present invention, and FIG. 2 illustrates the electronic element and the CPU of FIG. 1. Referring to FIGS. 1 and 2, the desktop personal computer 100 includes a motherboard 200 mounted in a housing (not shown) and a thermal module 300. The motherboard 200 includes a circuit carrier 210, a CPU 220, and a plurality of electronic elements 230. The CPU 220 and the electronic elements 230 are mounted on the circuit carrier 210. The electronic elements 230 include a PWM 232, a south bridge chip 234, and a north bridge chip 236.

The thermal module 300 includes a first heat sink 310 disposed above the CPU 220. In this embodiment, the first heat sink 310 is, for example, a fin type heat sink. In another embodiment (not illustrated), the thermal module 300 may further include a liquid cooling device, and the first heat sink 310 may be replaced with a cooling head of the liquid cooling device.

In addition, the thermal module 300 includes a plurality of second heat sinks 320 disposed above the electronic elements 230, respectively. In this embodiment, the second heat sinks 320 are, for example, fin type heat sinks.

In addition, the thermal module 300 further include a heat conductive plate 330. The heat conductive plate 330 may be comprised of metal or other materials having high thermal conductivity. The heat conductive plate 330 is coupled to one of the second heat sinks 320, for example, the second heat sink 320 above the PWM 232. The heat conductive plate 330 extends from this second heat sink 320 to the CPU 220, and is engagingly sandwiched between the CPU 220 and the first heat sink 310. Therefore, this heat conductive plate 330 makes it possible that heat of the electronic element 230 (i.e. the PWM 232) and the CPU 220 can be dissipated cooperatively by the first heat sink 310 and the second heat sink 320 above the PWM 230.

In this embodiment, the thermal module 300 may further include a plurality of heat pipes 340. One of the heat pipes 340 is coupled between two of the second heat sinks 320, such that the first heat sink 310 and the second heat sinks 320 are connected in series through the heat conductive plate 330 and the heat pipes 340. Therefore, the heat generated by the electronic elements 230 can be transferred to the first heat sink 310, or the heat generated by the CPU 220 can be transferred to the second heat sinks 320, thereby enhancing the cooling efficiency.

In summary, in the present invention, the heat generated by the electronic elements during operation can be transferred to the first heat sink through the heat conductive plate, and dissipated by the first heat sink, or the heat generated by the CPU can be transferred to the second heat sink through the heat conductive plate, and dissipated by the second heat sinks. Therefore, the heat conductive plate makes it possible that the heat of the CPU and the electronic elements can be dissipated cooperatively by the first heat sink and the second heat sinks.

In addition, the present invention includes at least one heat pipe coupled between two of the second heat sinks, such that the heat conductive plate and the heat pipe make it possible that the heat of the CPU and the electronic elements can be dissipated cooperatively by the first heat sink and the second heat sinks.

Furthermore, the heat conductive plate of the present invention is suitable in conventional cooling systems for CPUs. As such, the cooling result of the thermal module can be improved without increasing too much cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thermal module, suitable for a desktop personal computer comprising a motherboard including a central processing unit and plurality of electronic elements, the thermal module comprising:
a first heat sink, disposed above the central processing unit;
at least one second heat sink, disposed above one of the electronic elements; and
a heat conductive plate, coupled to the second heat sink, extending from the second heat sink to the central processing unit and engagingly sandwiched between the central processing unit and the first heat sink.

2. The thermal module according to claim 1, wherein the heat conductive plate comprises a metal plate.

3. The thermal module according to claim 1, wherein the first heat sink includes a cooling head of a liquid cooling device.

4. The thermal module according to claim 1, wherein the first heat sink comprises a fin type heat sink.

5. The thermal module according to claim 1, wherein the second heat sink comprises a fin type heat sink.

6. The thermal module according to claim 1, further comprising:
at least one heat pipe; and
a plurality of the second heat sinks, disposed above the electronic elements respectively, wherein the heat conductive plate extends from one of the second heat sinks onto the central processing unit and is engagingly sandwiched between the central processing unit and the first heat sink, and the heat pipe interconnects the second heat sinks.

7. The thermal module according to claim 6, wherein the first heat sink and the second heat sinks are connected in series through the heat conductive plate and the heat pipe.

8. A desktop personal computer comprising:
a motherboard, including a circuit carrier, a central processing unit mounted on the circuit carrier, and a plurality of electronic elements mounted on the circuit carrier;
a thermal module, including:
a first heat sink, disposed above the central processing unit;
at least one second heat sink, disposed above one of the electronic elements; and
a heat conductive plate, coupled to the second heat sink, extending from the second heat sink to the central processing unit and engagingly sandwiched between the central processing unit and the first heat sink.

9. The desktop personal computer according to claim 8, wherein the heat conductive plate comprises a metal plate.

10. The desktop personal computer according to claim 8, wherein the electronic elements include a pulse width modulator, a south bridge chip and a north bridge chip.

11. A desktop personal computer in accordance with claim 8, further comprising:
at least one heat pipe; and
a plurality of the second heat sinks, disposed above the electronic elements respectively, wherein the heat conductive plate extends from one of the second heat sinks onto the central processing unit, and is engagingly sandwiched between the central processing unit and the first heat sink, the heat pipe interconnecting the second heat sinks.

12. The desktop personal computer according to claim 11, wherein the heat conductive plate is coupled between the first heat sink, and the second heat sink above the pulse width modulator.

13. The desktop personal computer according to claim 11, wherein the first heat sink and the second heat sinks are connected in series through the heat conductive plate and the heat pipe.

14. The desktop personal computer according to claim 8, further comprising a housing, wherein the circuit carrier is located inside the housing, and the first heat sink includes a cooling head of a liquid cooling device.

15. The desktop personal computer according to claim 8, wherein the first heat sink comprises a fin type heat sink.

16. The desktop personal computer according to claim 8, wherein the second heat sink comprises a fin type heat sink.
